(19) United States
(12) Patent Application Publication
(10) Pub. No.: US 2026/0343825 A1
(43) Pub. Date: Oct. 29, 2026

(54) COOLING CABINET SYSTEMS AND METHODS

(71) Applicant: Dynamic Data Centers Solutions, Inc., San Diego, CA (US)

(72) Inventors: Paul Michael Bartlett, Travelers Rest, SC (US); Thomas Anthony Demitras, Waterford, PA (US)

(73) Assignee: Dynamic Data Centers Solutions, Inc., San Diego, CA (US)

(21) Appl. No.: 19/656,809

(22) Filed: Apr. 23, 2026

Related U.S. Application Data
(60) Provisional application No. 63/793,417, filed on Apr. 23, 2025.

(51) Int. Cl. H05K 7/20

(52) U.S. Cl. CPC H05K 7/20736; H05K 7/20145; H05K 7/20836

(57) ABSTRACT

Systems and methods are directed toward cooling electronics enclosures using one or more cooling cabinets coupled to corresponding electronics enclosures. The cooling cabinets include controlled air flow paths with fans, cooling coils, and one or more flow control devices to selectively permit cooling air within one cooling cabinet to flow into another cooling cabinet. Sensor-based control systems monitor operating conditions and dynamically regulate airflow and air transfer to provide redundant cooling, improve thermal efficiency, and mitigate overheating during failure or increased load conditions.

### CROSS-REFERENCE TO RELATED APPLICATIONS

This application claims priority to and the benefit of U.S. Provisional Patent Application No. 63/793,417, filed Apr. 23, 2025, titled “COOLING CABINET SYSTEMS AND METHODS,” the full disclosure of which is hereby incorporated by reference in its entirety for all purposes.

### BACKGROUND

Computer equipment and related support equipment may be housed in “racks.” Facilities known as datacenters may be used to house and manage multiple racks, which may be used in a variety of applications, such as distributed computing applications. In operation, the electronic equipment may be considered heat generating components that emit heat responsive to electrical energy used to perform one or more tasks. These components may have particular operational parameters, for example high temperature parameters, and/or operational setpoints based on efficiency determinations. As a result, datacenters and their associated racks are often cooled such that heat may be dissipated away from the electronic components to enable continued operation of the computer equipment according to one or more parameters.

Often, air cooling is used to remove heat from the racks and/or individual electronic components. For example, external airflow may be directed into an enclosure that functions to remove or otherwise carry heated air away from the electronic components. In certain configurations, datacenters may be configured to distribute air among a number of racks of electronic components using a centralized fan (or blower). For example, air within the datacenter may pass through a heat exchanger for cooling the air (e.g., an evaporator of a vapor-compression cycle refrigeration cooling system or “vapor-cycle” refrigeration) or a chilled water coil. In some datacenters, the heat exchanger is mounted to the rack to provide “rack-level” cooling of air. In other datacenters, the air is cooled before entering the datacenter.

In general, a lower air temperature in a datacenter allows each electronic component to dissipate a higher power (e.g., lower air temperature will facilitate greater cooling). Consequently, datacenters have traditionally used sophisticated air conditioning systems (e.g., chillers, vapor-cycle refrigeration, etc.) to cool the air (e.g., to about 65° F) within the datacenter for achieving a desired performance level. In general, spacing heat-dissipating components from each other (e.g., reducing heat density) makes cooling such components less difficult and hence less costly than placing the same components in close relation to each other (e.g., increasing heat density). Datacenters have also compensated for increased power dissipation (corresponding to increased server performance) by increasing the spacing between adjacent servers. However, it is inefficient to cool larger areas that are necessitated by increasing distance between racks.

Control systems have been used to increase cooling rates for a plurality of electronic components in response to increased computational demand. Even so, such control systems have controlled cooling systems that dissipate heat into the datacenter building interior air (which in turn needs to be cooled by air conditioning), or directly use refrigeration as a primary mode of heat dissipation. Refrigeration as a primary mode of cooling, directly or indirectly, requires significant amounts of energy.

As datacenters increase in size and components are designed to consume additional energy and/or handle greater loads, the amount of energy used to cool datacenters and associated components has increased. Additionally, high density facilities to support various processing applications, such as artificial intelligence (AI) processing, also lead to additional energy consumption, and as a result, more cooling load. One approach to larger datacenter loads has been to increase density of the datacenter, for example, by adding additional components to racks. Certain high density racks may require more than 50kW per rack. As discussed, traditional methods include cooling an entire building and exchanging the air from hot and cold aisles into the atmosphere while sustaining strict conditions of air quality. Such an approach consumes large amounts of energy, increases carbon emissions, and overall increases an environmental footprint for the industry.

### SUMMARY

Applicant recognized the problems noted above herein and conceived and developed embodiments of systems and methods, according to the present disclosure, for configurations that may be used with one or more cabinet enclosures.

In an embodiment, a system includes a cabinet having a first side and a second side. The system also includes a first fan arranged at the first side and a second fan arranged at the first side. The system further includes a third fan arranged at the second side. The system also includes a cooling coil positioned between the first side and the second side within an interior of the cabinet. The system may include a first fan axis parallel to a second fan axis and be configured such that both the first fan axis and the second fan axis are perpendicular to a third fan axis.

In an embodiment, a system includes a cabinet having a first side and a second side, a first fan arranged at the first side, a second fan arranged at the second side, and a cooling coil positioned between the first side and the second side within an interior of the cabinet, the cooling coil arranged within a duct establishing a flow path between the first fan and the second fan.

In an embodiment, a system includes a cabinet having a first side and a second side, a first fan arranged at the first side, a second fan arranged at the second side, and a cooling coil positioned between the first side and the second side within an interior of the cabinet, the cooling coil arranged within a duct establishing a flow path between the first fan and the second fan. The system also includes a damper arranged at the first side, the damper including moveable plates to regulate air flow into or out of the first side.

In an embodiment, a system includes a cabinet enclosure configured to receive one or more servers. The system also includes a cooling cabinet having a first side and a second side, a first fan arranged at the first side, a second fan arranged at the second side, and a cooling coil positioned between the first side and the second side within an interior of the cabinet. The cooling coil is arranged within a duct establishing a flow path between the first fan and the second fan. Additionally, the cooling cabinet is positioned axially lower than the cabinet enclosure and the cabinet enclosure is stacked on the cooling cabinet to receive an air flow from the cooling cabinet.

In an embodiment, a cooling system includes a plurality of electronics enclosures and a plurality of cooling cabinets. Each cooling cabinet of the plurality of cooling cabinets is attached to a corresponding electronics enclosure of the plurality of electronics enclosures. The cooling system also includes a coupling passage is arranged between a first cooling cabinet and an adjacent second cooling cabinet to selectively permit air transfer between the first and second cooling cabinets.

In an embodiment, a cooling cabinet is configured to be attached to an electronics enclosure and includes a cabinet housing. The cooling cabinet is configured for connection to a coupling passage arranged between the cooling cabinet and an adjacent cooling cabinet to selectively permit air transfer between the cooling cabinet and the adjacent cooling cabinet. The coupling passage includes a flow control device configured to block or permit the air transfer.

In an embodiment, method of operating a cooling system, which includes a plurality of cooling cabinets, each attached to a corresponding electronics enclosure, and a coupling passage between a first cooling cabinet and an adjacent second cooling cabinet, includes monitoring a property associated with the plurality of cooling cabinets. The method also includes determining a failure or insufficient cooling associated with the first cooling cabinet. The method further includes responsive to the determining, actuating the flow control device to permit air transfer through the coupling passage and transfer at least a portion of air between the first and second cooling cabinets.

### BRIEF DESCRIPTION OF THE DRAWINGS

Various embodiments in accordance with the present disclosure will be described with reference to the drawings, in which:

FIG. 1A illustrates an example schematic representation of a cooling configuration including a cabinet enclosure, in accordance with various embodiments.

FIG. 1B illustrates an example schematic representation of a cooling configuration including a cabinet enclosure, in accordance with various embodiments.

FIG. 1C illustrates an example schematic representation of a cooling configuration including a cabinet enclosure, in accordance with various embodiments.

FIG. 1D illustrates an example schematic representation of a cooling configuration including a cabinet enclosure, in accordance with various embodiments.

FIG. 2 illustrates an example schematic representation of a cabinet, in accordance with various embodiments.

FIG. 3A illustrates a perspective view of an embodiment of a plurality of cooling cabinets, in accordance with various embodiments.

FIG. 3B illustrates a perspective view of an embodiment of a plurality of cooling cabinets in which one or more panels are removed, in accordance with various embodiments.

FIG. 3C illustrates a side perspective view of an embodiment of a plurality of cooling cabinets in which one or more panels are removed, in accordance with various embodiments.

FIG. 4A illustrates a schematic representation of a pair of cooling cabinets coupled together via a coupling passage, in accordance with various embodiments.

FIG. 4B illustrates a schematic representation of a pair of cooling cabinets coupled together via a coupling passage, in accordance with various embodiments.

FIG. 4C illustrates a schematic representation of a plurality of cooling cabinets coupled together via one or more coupling passages, in accordance with various embodiments.

FIGS. 4D and 4E illustrate example control systems associated with one or more flow control devices, in accordance with various embodiments.

FIG. 5A is a flow chart of a process for adjusting air flow between cooling cabinets, in accordance with various embodiments.

FIG. 5B is a flow chart of a process for adjusting air flow between cooling cabinets, in accordance with various embodiments.

FIG. 6 is an example configuration for a computing device, in accordance with various embodiments.

FIG. 7A is an example configuration of a cooling section including variable flow control elements, in accordance with various embodiments.

FIG. 7B is a perspective view of a cooling section including variable flow control elements, in which one or more panels are removed, in accordance with various embodiments.

FIG. 7C is a perspective view of a cooling section including variable flow control elements, in which one or more panels are removed, in accordance with various embodiments.

FIG. 7D is a perspective view of a cooling section including variable flow control elements, in which one or more panels are removed, in accordance with various embodiments.

FIG. 8 illustrates a perspective view of an embodiment of a cooling configuration in which a cooling enclosure is on top of a cooling cabinet, in accordance with various embodiments.

### DETAILED DESCRIPTION

The foregoing aspects, features, and advantages of the present disclosure will be further appreciated when considered with reference to the following description of embodiments and accompanying drawings. In describing the embodiments of the disclosure illustrated in the appended drawings, specific terminology will be used for the sake of clarity. However, the disclosure is not intended to be limited to the specific terms used, and it is to be understood that each specific term includes equivalents that operate in a similar manner to accomplish a similar purpose. Additionally, like reference numerals may be used for like components, but such use should not be interpreted as limiting the disclosure. For example, one or more subsequent figures may share similar features with one or more prior figures and the similar features may be identified with like reference numerals for convenience purposes only and not to limit the scope of the present disclosure.

When introducing elements of various embodiments of the present disclosure, the articles “a”, “an”, “the”, and “said” are intended to mean that there are one or more of the elements. The terms “comprising”, “including”, and “having” are intended to be inclusive and mean that there may be additional elements other than the listed elements. Any examples of operating parameters and/or environmental conditions are not exclusive of other parameters/conditions of the disclosed embodiments. Additionally, it should be understood that references to “one embodiment”, “an embodiment”, “certain embodiments”, or “other embodiments” of the present disclosure are not intended to be interpreted as excluding the existence of additional embodiments that also incorporate the recited features. Furthermore, reference to terms such as “above”, “below”, “upper”, “lower”, “side”, “front”, “back”, or other terms regarding orientation or direction are made with reference to the illustrated embodiments and are not intended to be limiting or exclude other orientations or directions. Moreover, references to “substantially” or “approximately” or “about” may refer to differences within ranges of +/- 10 percent.

Embodiments of the present disclosure are directed towards one or more cabinet enclosures that may be used to house and/or support electronic components, including but not limited to servers or other silicon-chip packages. In at least one embodiment, the servers may refer to central processing units (CPUs), graphics processing units (GPUs), data processing units (DPUs), accelerators, and/or various support systems including switches, power supplies, and/or the like. One or more embodiments of the present disclosure may be directed toward cabinet enclosures that include fittings, seals, and production easements. In at least one embodiment, the fittings, seals, and/or manufacturing processes may generate a cabinet enclosure in compliance with one or more industry standards, such as National Electrical Manufacturers Association (NEMA) 3R.

Various embodiments of the present disclosure may be directed toward one or more cabinet enclosures, which may include a “top cabinet” or “cooling cabinet” associated with a cooling air flow and a “bottom cabinet” or “electronics cabinet” for storing and/or positioning various electronic components, which as discussed herein, may be heat producing components in that heat is dissipated from the electronic components responsive to a load (e.g., an electric load). One or more embodiments may also refer to structures in which the “cooling cabinet” is a “bottom cabinet” such that the “electronics cabinet” is positioned on top of or stacked above the “cooling cabinet.” Systems and methods may include one or more interface elements and/or manufacturing processes in order to reduce costs and meet certain industry specification, such as NEMA compliance, among other options. Accordingly, the provided manufacturing easement and/or compliance measures may be used to both reduce manufacturing costs and also provide an improved cabinet enclosure less susceptible to leaks and/or loss of cooling air flow.

Systems and methods of the present disclosure may also be directed toward providing a specified and/or desired quantity of cooling air flow, which may be based on a number of factors. For example, in at least one embodiment, cooling capacity may be measured as a function of flow in cubic feet per minute (CFM). As another example, temperature (T) may be a metric used to measure cooling air flow. As discussed herein, cooling capacity may be considered as a function per kilowatt (kW). That is, cooling may be evaluated as a measure of CFM/kW, T/kW, and/or the like. In at least one embodiment, systems and methods of the present disclosure may incorporate multiple fan arrangements, which may include arranging fans in series, in parallel, and/or combinations thereof. Furthermore, embodiments may position various portions of different cooling components, such as fans, external to the cabinet enclosure, thereby addressing motor cooling and other factors. Additionally, moving components to different areas of the cabinet enclosure may provide more air flow and/or volume through which to acquire and/or move cooling air. For example, it may be desirable to increase a space around a fan (e.g., a plenum) in order to direct cooling air through the fan and into a cooling region in which heat exchange may take place with one or more coils, which may be associated with a cooling water flow.

Systems and methods of the present disclosure may be directed toward cabinet enclosures that have a variety of different size configurations in order to accommodate different numbers of electronic components, different cooling capacities, different fan configurations, and/or the like. By way of example, systems and methods may be directed toward cabinet enclosures having a width of approximately 24 inches. In at least one embodiment, the width may be increased by a percentage, such as approximately 25%, in order to produce a cabinet enclosure with a width of approximately 30 inches. Such a configuration may increase performance by approximately 30%.

At least one embodiment may include a transfer system (e.g., lateral transfer system, bleed system, etc.) to allow diversion or movement of air (e.g., cold air, hot air, cooled air, heated air, etc.) from one cabinet to an adjacent cabinet. Transfer of air may be between cooling cabinets, electronics cabinets, and/or combinations thereof. By way of example, a transfer system may be used to redirect a portion of cold air flow to an adjacent cabinet, for example responsive to a power loss or other failure. As another example, the transfer system may be used to redirect a portion of heated air flow from one cabinet to an adjacent cabinet. As discussed herein, transfer between “cabinets” may refer to one or both of the cooling cabinet or the electronics cabinet. One or more embodiments may implement a control system to monitor one or more metrics (e.g., fan speed, cooling water flow, etc.) and, upon a determination of one or more thresholds corresponding to states such as failure, insufficient cooling, and/or the like, may activate one or more selective transfer systems to redirect a portion of flow into one or more sections of an adjacent, or otherwise connected, cabinet. In this manner, temperature may be controlled during remediation actions.

One or more embodiments of the present disclosure are directed toward a redundant cooling cabinet system that may provide “lateral transfer” including at least one or more of adjacent cabinet coupling, multi-cabinet coupling, and/or control systems that may be responsive to determinations associated with one or more scenarios. One or more embodiments of the present disclosure may include one or more pairs of adjacent cabinets coupled by a coupling passage enabling selective air transfer. Selective air transfer may be provided between one or more cooling cabinet portions, which may include at least one fan, a heated air plenum (e.g., for air that has been heated in the electronics cabinet), a cooling coil, and a cooling air plenum (e.g., for air that has been cooled by the cooling coil). A coupling passage may extend between portions of the cooling cabinet associated with at least one of the cooling air plenum or the heated air plenum. Furthermore, one or more flow control devices may be associated with the coupling passage to selectively permit air to flow between the adjacent cabinets. As discussed herein, flow control devices may be associated with the cooling air plenum, the heated air plenum, and/or combinations thereof. The flow control devices may be independently controllable to selectively permit air flow between adjacent cabinets, which may be based, at least in part, on one determined metrics from information collected by one or more sensors. For example, in one or more embodiments, a control system may monitor and actuate at least one flow control device upon determination that one or more metrics exceeds a threshold and/or falls outside of a range, which may include determinations associated with operational states such as failure/insufficient cooling. Various properties and/or metrics may be monitored, including temperatures at different portions of the cooling cabinet, temperatures at different portions of the electronics cabinet, fan speed, air flow rates, cooling fluid flow rates, power consumption, and/or the like. Furthermore, in at least one embodiment, associated components, such as the fan(s) and/or the cooling coil, may also be controlled by the control system and may adjust operations based on the one or more determinations associated with operational states, such as increasing/decreasing fan speeds, increasing/decreasing air flow rates, increasing/decreasing cooling fluid flow rates, and/or the like.

One or more embodiments of the present disclosure may be associated with a cooling system that includes a plurality of electronics enclosures and a plurality of cooling cabinets. One or more cooling cabinets of the plurality of cooling cabinets may be coupled (e.g., attached, fluidly coupled, etc.) to a corresponding electronics enclosure of the plurality of electronics enclosures. In at least one embodiment, a coupling passage is arranged between a first cooling cabinet and an adjacent second cooling cabinet to selectively permit air transfer between the first and second cooling cabinets. Each cooling cabinet may include at least one or more of a heated-air plenum, a cooling coil through which air supplied from the heated-air plenum passes, a cooling-air plenum into which air having passed through the cooling coil flows, and a fan configured to drive air. It should be appreciated that different cooling cabinets may include more or fewer components than other or adjacent cabinets. For example, certain cabinets may include multiple fans. As another example, certain cabinets may include multiple cooling coils. By way of example, an arrangement may include certain cooling cabinets that increased or enhanced cooling capabilities as fallback or redundancy, such as cooling cabinets with multiple cooling coils, larger fans, more fans, and/or the like. In operation, the coupling passage is configured to couple a cooling-air plenum of the first cooling cabinet with a cooling-air plenum of the second cooling cabinet and a flow control device (e.g., a first flow control device, a selective flow control device, etc.) is configured to block or permit air transfer through the coupling passage. Furthermore, in certain embodiments, a return passage couples a heated-air plenum of a first cooling cabinet with a heated-air plenum of a second cooling cabinet and another flow control device (e.g., a second flow control device) associated with the return passage is configured to block or permit air transfer through the return passage. As discussed herein, various embodiments may be used to control operation of the different flow control devices and/or associated components (e.g., fans, cooling fluid flow rates, etc.), which using one or more control systems (e.g., controllers) that may monitor one or more properties (e.g., metrics) associated with the plurality of cooling cabinets, or a singular cabinet, and responsive to a determination of a failure or insufficient cooling associated with the first cooling cabinet, actuate the first flow control device to permit air transfer through the coupling passage, and actuate the second flow control device to permit air transfer through the return passage, to transfer at least a portion of air between the first and second cooling cabinets. As an example, properties controlled by the control system may include at least one of fan speed or cooling water flow, which may include increasing at least one of the fan speed or an airflow rate of the fan in the second cooling cabinet.

Systems and methods of the present disclosure may be directed toward a cooling cabinet configured to be attached to an electronics enclosure that includes a cabinet housing configured to be connected to at least an adjacent cooling cabinet via one or more coupling passages. As discussed herein, the coupling passages may be used to selectively permit air transfer between the cooling cabinet and the adjacent cooling cabinet, which may include controlling one or more flow control devices configured to block or permit the air transfer. The cooling cabinet may also include an internal air path having an ordered arrangement of a heated-air plenum, a cooling coil, a fan, and a cooling-air plenum, with respect to an upstream side toward a downstream side. In at least one embodiment, the fan is a centrifugal fan having an axis along a flow direction, and an outlet of the cooling cabinet is located downstream of an outlet of the centrifugal fan in the flow direction.

Various embodiments of the present disclosure may also include a method of operating a cooling system that includes a plurality of cooling cabinets, each attached to a corresponding electronics enclosure. In embodiments, the cooling system includes a coupling passage between a first cooling cabinet and an adjacent second cooling cabinet and the coupling passage including a flow control device. In operation, a method of control may include monitoring a property associated with the plurality of cooling cabinets, determining a failure or insufficient cooling associated with the first cooling cabinet, and responsive to the determining, actuating the flow control device to permit air transfer through the coupling passage and transfer at least a portion of air between the first and second cooling cabinets.

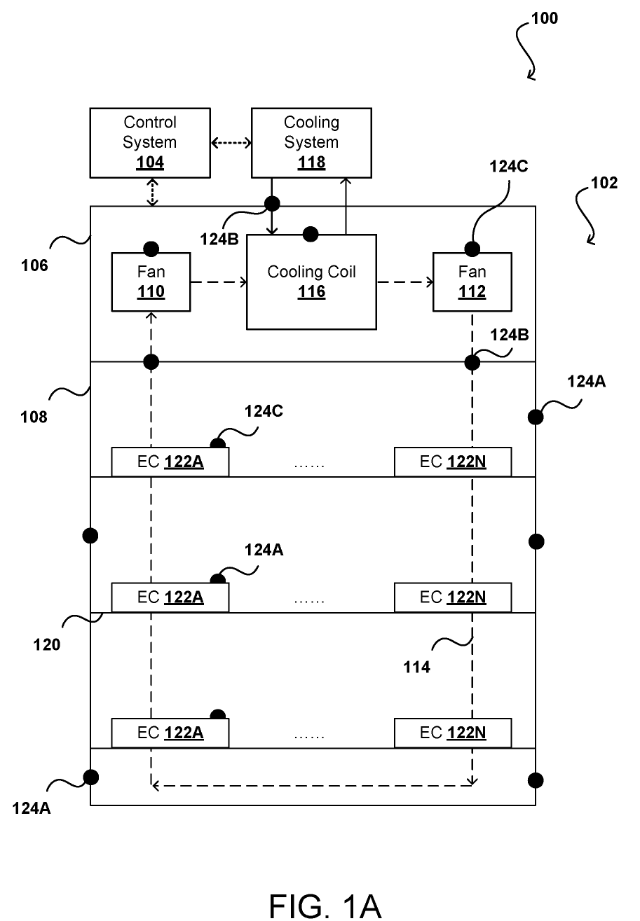

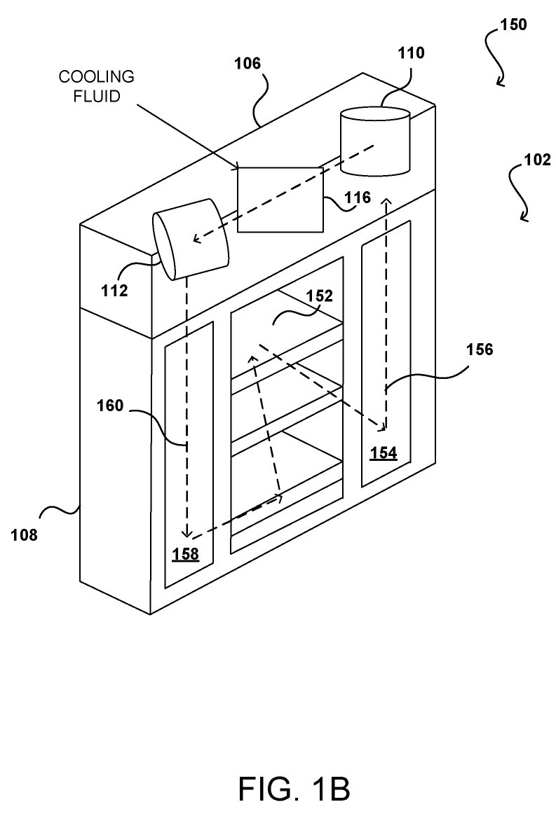

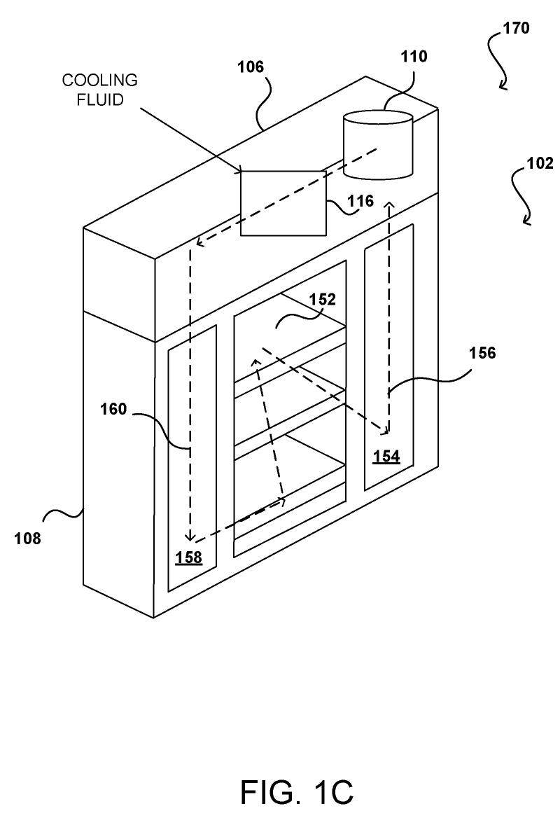

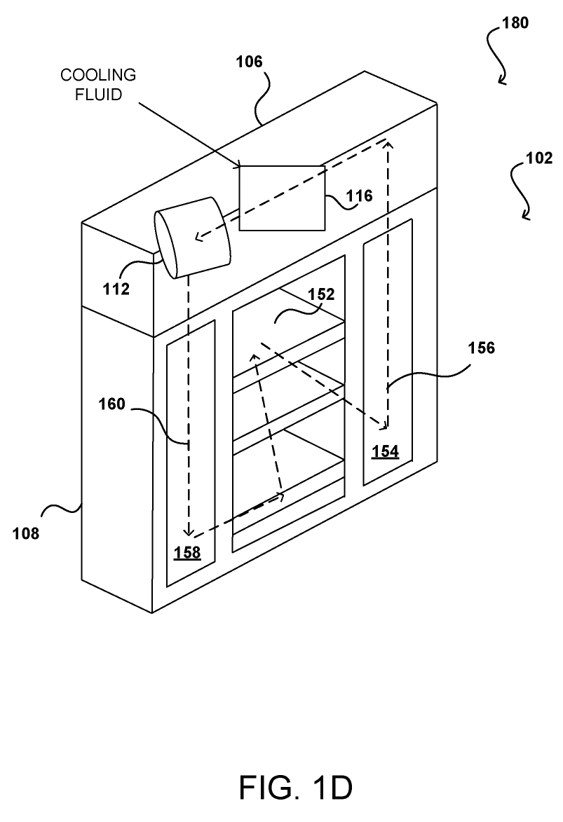

FIG. 1A illustrates an example environment 100 that may be used with embodiments of the present disclosure. This example includes a cabinet enclosure 102, which may also be referred to as a cooling cabinet, cabinet, server cabinet, enclosure, and/or the like. The cabinet enclosure 102 may be arranged within a datacenter, for example among a variety of other cabinet enclosures (not pictured) and/or with traditional datacenter arrangements including hot/cold aisles, among other configurations. Accordingly, systems and methods may be directed toward a mobile, deployable, and separately controllable cabinet enclosure 102 that may use one or more control systems 104 to regulate operational parameters of the cabinet enclosure 102 and/or components thereof. In at least one embodiment, the cabinet enclosure 102 may correspond to one or more enclosures from DDC®, such as an S-Series or R-Series cabinet, among various other options. In at least one embodiment, the cabinet enclosure 102 may include one or more features associated with and/or described in U.S. Patent Application No. 17/652,323 or U.S. Patent Application No. 17/648,174, each of which are hereby incorporated by reference in their entireties for all purposes.

The illustrated cabinet enclosure 102 includes a cooling section 106 (e.g., a cooling cabinet) and a storage section 108 (e.g., an electronics enclosure), but it should be appreciated that these regions are described by way of non-limiting example only and are not intended to limit the scope of the present disclosure. The illustrated cooling section 106 includes a pair of fans 110, 112 in a push/pull configuration to direct a flow of air 114 over a cooling coil 116. In at least one embodiment, the push/pull configuration may refer to fan pairs having perpendicular axes (e.g., perpendicular axes of rotation for fan blades). The push-pull configuration is provided by way of non-limiting example only, and various embodiments of the present disclosure may be used with different types of fan arrangements, fan/liquid arrangements, and/or the like. For example, a single fan may be used with embodiments of the present disclosure. Furthermore, more than two fans may be used in one or more embodiments. The cooling coil 116 may receive cooling fluid (e.g., gas, liquid, solid, combinations thereof), such as water, glycol, and/or the like, from a cooling system 118. As discussed herein, in at least one embodiment, the control system 104 may be used to regulate or otherwise control one or more operational parameters of the cabinet enclosure 102, which may include components of the fans 110, 112, cooling coil 116, cooling system 118, and/or the like. In at least one embodiment, the cooling system 118 may include one or more heat exchangers, pumps, valves, and/or the like to direct cooling fluid to the cooling coil 116. In operation, as the air 114 passes over/through the cooling coil 116, heat may dissipate away from the air 114, which is then redirected through the storage section 108 to cool the components therein, as illustrated by the dashed arrow.

In this example, the storage section 108 includes a number of racks 120 that may be used to house, support, or otherwise store one or more electronic components 122, which may include components such as CPUs, GPUs, DPUs, accelerators, servers, memory units, switches, control systems, power supplies, and/or the like. The different electronic components 122 may generate heat during operation and the air 114 may be used to cool the electronic components 122 by directing the heated air from operation away in favor of the cooled air 114. In this manner, operation of the electronic components 122 may be maintained at one or more desired parameters, which may correspond to a temperature of the electronic components 122, an internal temperature of the storage section 108, a cooling capacity per load, a tonnage, a flow rate, and/or the like or combinations thereof.

Various embodiments may include one or more sensors 124 positioned within the cabinet enclosure 102 and/or associated with equipment supporting the cabinet enclosure 102. By way of non-limiting example, various sensors 124 such as temperature sensors, flow rate sensors, pressure sensors, humidity sensors, pH sensors, valve position sensors, load sensors, fan sensors, proximity sensors, and/or the like may be incorporated into the cabinet enclosure 102 and/or supporting equipment in order to monitor one or more parameters of the cabinet enclosure 102. In at least one example, temperature sensors 124A may be used at different locations within the cabinet enclosure 102 to measure temperature, for example at a top cabinet location and a bottom cabinet location, among others. Information acquired by the temperature sensors 124A may be used to determine (e.g., calculate, infer, etc.) temperature differentials and/or adjust one or more operating conditions. Temperature information may also be used for data visualization, such as to establish a temperature gradient and/or to illustrate and model airflow through the storage section 108. For example, if temperature were to increase in one area of the cabinet enclosure 102, a cooling fluid flow rate may be increased to the cooling coil 116, which would lead to cooler air 114, and therefore more cooling within the storage section 108. As another non-limiting example, one or more flow sensors 124B may be used to monitor airflow rates and/or cooling fluid rates. The airflow rates may be used to determine (e.g., calculate, infer, etc.) fan speeds or motor loads for the fans 110, 112. In at least one embodiment, cooling fluid flow rates may be used to determine (e.g., calculate, infer, etc.) pump operational parameters, valve position, flow line fouling, pressure differentials, and/or the like. Similarly, separate sensors may also be deployed for use with the motors associated with the fans 110, 112. In another example, sensors may be deployed to measure valve position with respect to the cooling system 118 and, based on one or more other parameters, valve position may be adjusted to increase or decrease cooling water flow to the cooling coil 116. Additionally, in at least one embodiment, load may be measured with respect to an energy draw for one or more components within the cabinet enclosure 102. By way of non-limiting example, one or more load sensors 124C may be used to determine a load drawn by the electronic components, a load drawn by the fans 110, 112, and/or the like. In this manner, different sensors 124 may be deployed to collect information associated with the internal environment of the cabinet enclosure 102 and/or with the supporting systems associated with the cabinet enclosure 102 and then that information may be used to adjust and regulate one or more different operating conditions in accordance with different control parameters discussed herein.

FIG. 1B illustrates an example schematic perspective view of an environment 150 that may be used with embodiments of the present disclosure. The cabinet enclosure 102 is shown with various features omitted for clarity and conciseness. Moreover, features have been “cut out,” made transparent, or otherwise removed in order to provide illustrative examples of different regions of the cabinet enclosure 102 and/or airflow. In this example, the cooling section 106 and the storage section 108 are shown in a stacked configuration, with the fans 110, 112 and cooling coil 116 arranged in the cooling section 106 and various racks 152 to support different electronic and/or heat generating components in the storage section 108. The non-limiting example configuration shows a dual-fan system, but it should be appreciated that more or fewer fans may be used in various embodiments. Furthermore, stacking the cooling section 106 on top of the storage section 108 is also provided by way of non-limiting example. For example, the storage section 108 may be above the cooling section 106 and/or in a substantially side-by-side configuration. During operation, the fan 110 is fluidly coupled to an exhaust-side region 154 (e.g., hot aisle, hot deck), receiving a heated airflow along a flow path 156. The exhaust-side region 154 may refer to a passage along a side of the storage section 108, a “rear” or “back” of the storage section 108 as air is driven over the components, and/or combinations thereof. The exhaust-side region 154 may also, or alternatively, extend at least partially into one or both of the cooling section 106 and/or the storage section 108. The fan 110 receives and directs the heated air of the flow path 156 across the coil 116, which may receive a cooling fluid to remove heat from the heated air of the flow path 156. As shown, cooled air is then directed to the fan 112, which in this example is fluidly coupled to an intake-side region 158 (e.g., cold aisle, cold deck). Much like the exhaust-side region 154, the intake-side region 158 may refer to a passage along a side of the storage section 108, a “front” of the storage section 108 as air is driven over the components, and/or combinations thereof. The intake-side region 158 may also, or alternatively, extend at least partially into one or both of the cooling section 106 and/or the storage section 108. Accordingly, the intake-side region 158 is used to direct the cooled airflow along a flow path 160 into the storage section 108 and/or to direct the cooled airflow along the flow path 160 by forming at least a portion of the storage section 108. In at least one embodiment, one or more channels or passages may be used to then direct the flow path 160 across or along the racks 152, which may receive and support different equipment. Flow may be directed in a front-to-back direction, across, and/or combinations thereof. Once heat is absorbed by the cooled air of the flow path 160, the flow path is converted into the heated flow path 156 and the process may be repeated to circulate air throughout the cabinet enclosure 102. Cooling associated with the cabinet enclosure 102 may, therefore, be described as directing cooling airflow (e.g., the flow path 160) from the cooling section 106 into the intake side region 158 (which as discussed herein, may include portions of the storage section 108 and/or the cooling section 106) to the storage section 108, where the airflow, along the flow path 160, is heated at the racks 152 via heat emitted from one or more rack components, which is then returned to the cooling section 106 via the exhaust-side region 154 (which as discussed herein, may include portions of the cooling section 106 and/or the storage section 108). As discussed herein, the cabinet enclosure 102 may be sealed or substantially sealed, for example sealing may comply with one or more NEMA standards, and as a result, the airflow within the cabinet enclosure 102 may be substantially contained and separated from an ambient environment associated with the cabinet enclosure 102. For example, the cabinet enclosure 102 may be arranged within a datacenter that has an ambient temperature of approximately 80 degrees, but the interior of the cabinet may be approximately 68 degrees due to the isolated cooling environment formed by the cooling section 106.

As discussed herein, different areas or regions of the cabinet enclosure 102 may experience different pressure and/or temperature events. For example, if a server positioned on a central rack suddenly “spools up,” its temperature may spike rapidly and be greater than the temperature of other racks or areas of the cabinet enclosure. One or more embodiments of the present disclosure may be configured to identify such spikes, either due to pressure, temperature, and/or the like, and automatically adjust one or more flow properties of the cabinet enclosure by adjusting one or more of a flow area within the storage section 108, a flow area within the cooling section 106, a flow area of the exhaust-side region 154, a flow area of the intake-side region 158, and/or a fluid connection between the cabinet enclosure and the ambient environment. Increased density associated with cabinets, discussed herein, may cause more heat, challenges with airflow, and uneven cooling. Embodiments of the present disclosure provide an adaptive variable flow control element to adjust to the challenges of modern cabinets by using a differential pressure as at least one driving factor behind a variable flow control element that can be used to regulate airflow between the intake-side region and the exhaust-side region. Furthermore, embodiments of the present disclosure may also be used to adjust and/or regulate variable flow control element positions based on one or more other sensor readings, such as temperature, cooling flow rates, airflow volume, fan speed, and/or the like.

FIGS. 1C and 1D illustrate example schematic perspective views of environment 170, 180 that may be used with embodiments of the present disclosure. The cabinet enclosures 102 are shown with various features omitted for clarity and conciseness. Moreover, features have been “cut out,” made transparent, or otherwise removed in order to provide illustrative examples of different regions of the cabinet enclosures 102 and/or airflow. In the example configurations of FIGS. 1C and 1D, a singular fan is used, as opposed to the non-limiting dual-fan configuration of FIG. 1B. In FIG. 1C, the fan 112 is omitted, and in FIG. 1D, the fan 110 is omitted. It should be appreciated that the configuration of the fans 110, 112 may be adjusted based on a variety of different factors, and therefore, the orientations shown in FIGS. 1C and 1D are not intended to limit the scope of the present disclosure.

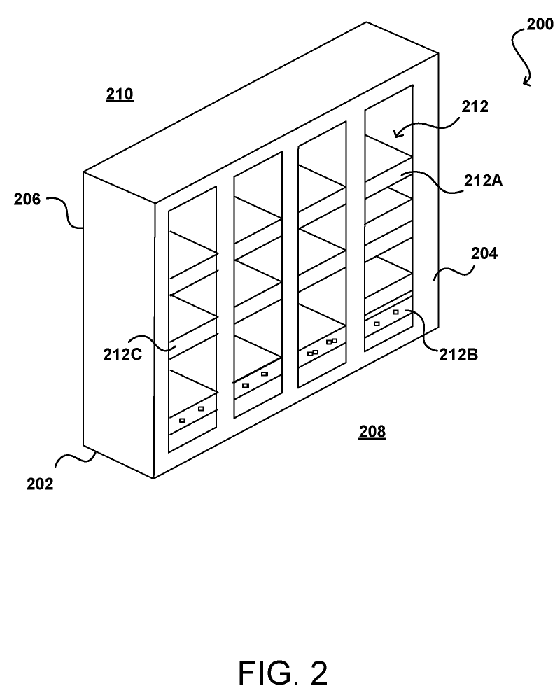

One or more embodiments of the present disclosure may also be used, at least in part, with non-sealed cabinets, as shown in the example environment 200 of FIG. 2. The configuration includes a cabinet 202 (e.g., enclosure, server enclosure, etc.) with a front side 204 and a back side 206. As discussed herein, the front side 204 may correspond to an intake-side region 208 (e.g., cold aisle) and the back side 206 may correspond to an exhaust-side region 210 (e.g., hot aisle). For example, cooling air may enter one or more portions of the cabinet 202 at the front side 204, be directed over one or more cabinet components 212 to remove heat, and then exhaust out of the back side 206 into the exhaust-side region 210. In at least one embodiment, cabinet components 212 may refer to one or more components mounted in the one or more server racks (e.g., the cabinet components may be separate and/or independent from the server racks themselves). By removing the heat from the one or more cabinet components 212, air in the exhaust-side region 210 will have a temperature that is greater than air in the cold aisle 208. The difference in temperature may further lead to a difference in pressure (e.g., a differential across the cabinet 202), which may affect, at least in part, airflow across the one or more cabinet components 212. Embodiments of the present disclosure may be directed toward using one or more of a pressure differential, a temperature differential, and/or the like to adaptively control flow across the cabinet.

In at least one embodiment, the one or more cabinet components 212 may include a variety of different components, such as servers 212A, power supplies 212B, compute units 212C (e.g., GPUs, CPUs, DPUs, accelerators, etc.), and/or the like. While not shown for simplicity, various embodiments may also include wiring or other cabling extending between the different cabinet components 212 within the cabinet 202.

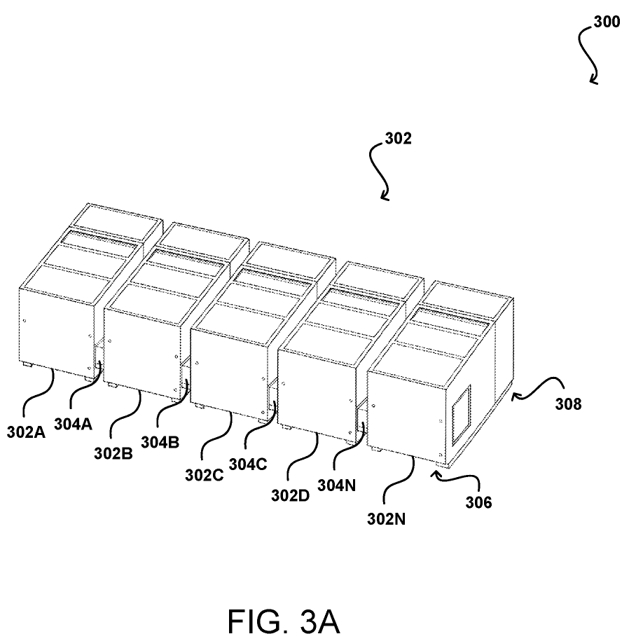

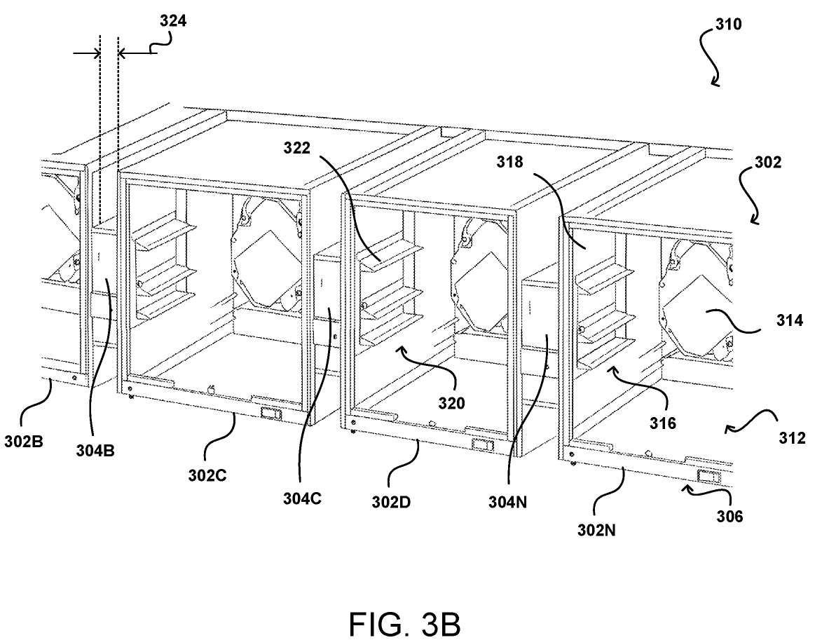

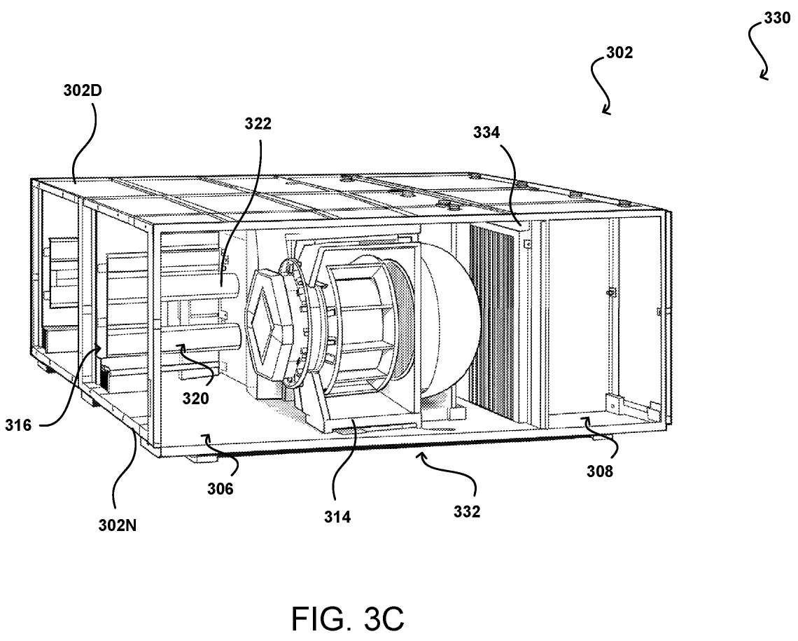

FIG. 3A illustrates an example environment 300 that may be used with embodiments of the present disclosure to incorporate one or more selective transfers between one or more cabinets. In this example, a plurality of cooling cabinets 302 are arranged in a side-by-side configuration to position at least one cooling cabinet 302 in a pair of cooling cabinets 302 adjacent to another cooling cabinet 302 in the pair of cooling cabinets 302. The non-limiting configuration includes five cooling cabinets 302, which may each be individually coupled to an associated electronics cabinet (not pictured), but it should be appreciated that there may be more or fewer cooling cabinets 302 in various embodiments. The illustrated plurality of cooling cabinets 302 includes cooling cabinets 302A-302N arranged such that the cooling cabinet 302A is adjacent to the cooling cabinet 302B, the cooling cabinet 302B is adjacent to the cooling cabinet 302A and the cooling cabinet 302C, the cooling cabinet 302C is adjacent to the cooling cabinet 302B and the cooling cabinet 302D, the cooling cabinet 302D is adjacent to the cooling cabinet 302C and the cooling cabinet 302N, and the cooling cabinet 302N is adjacent to the cooling cabinet 302D.

In the example configuration, each of the adjacent cooling cabinets 302 are fluidly coupled together via one or more coupling passages 304 (e.g., transfer passages, jumpers, bleed passages, etc.). As shown, certain configurations may include more or fewer coupling passages. For example, because the cooling cabinet 302A is adjacent to only one other cooling cabinet (e.g., the cooling cabinet 302B), a single coupling passage 304A is shown coupled to the cooling cabinet 302A. In contrast, because the cooling cabinet 302B is adjacent to two cooling cabinets (e.g., the cooling cabinet 302A and the cooling cabinet 302C), two coupling passages 304A, 304B are coupled to the cooling cabinet 302B. Similar configurations are shown in FIG. 3A for illustrative purposes, but it should be appreciated that other coupling arrangements may be formed within the scope of the present disclosure, such as coupling passages that are not limited to only adjacent cooling cabinets (e.g., a coupling passage may extend between the cooling cabinet 302A and the cooling cabinet 302C). Similarly, embodiments may be described that use different cooling cabinets 302 as “pass through systems” between other non-adjacent cooling cabinets, such as using the cooling cabinet 302B as a pass through for transfer between the cooling cabinet 302A and the cooling cabinet 302C.

In the illustrated configuration shown in FIG. 3A, the coupling passages 304 are arranged at and/or adjacent to respective cooling-air plenums 306 of the cooling cabinets 302A-302N. That is, the position of the coupling passages 304 may be associated with air that has been cooled via one or more cooling coils (not pictured) positioned within a flow path (not pictured) within the cooling cabinet that extends from a heated-air plenum 308, moves along the flow path over the cooling coil, and toward the cooling-air plenum 306. Accordingly, the example configuration could be used to direct cooled air into adjacent cooling cabinets 302. As discussed herein, embodiments are not limited to the use of the coupling passages 304 at the cooling-air plenums 306 and, in various embodiments, coupling passages 304 may also, or alternatively, be arranged at one or more other locations, such as at the heated-air plenums 308, along the flow path between heated-air plenums 308 and the cooling-air plenums 306, and/or the like.

In operation, the coupling passages 304 may be formed of ducting or other structure material and may include, as discussed herein, one or more flow control devices (not pictured) to permit or block flow between the adjacent cabinets 302. However, the inclusion of ducting that positions the cabinets as a spaced distance apart is by way of example only and, in other embodiments, the cabinets may be flush/in contact and the coupling passages 304 may be formed by cutouts or removal of removal that is aligned between adjacent cooling cabinets 302.

In at least one embodiment, one or more selective flow control devices (e.g., valves, slats, louvers, dampers, deflectors, baffles, regulators, etc.) may be arranged along the coupling passages 304 and/or formed within or otherwise associated with the respective cooling cabinets 302 to block or permit flow based on a position of the flow control device. The position may be based, at least in part, on a control signal received in response to monitoring one or more properties of the cooling cabinets 302, the associated electronics cabinets, properties of the cooling coil, properties of the fan(s), and/or the like. Accordingly, responsive to a determination of a state change (e.g., a failure, an inefficiency, etc.) flow may be permitted through the coupling passages 304 to redirect a portion of cooling air flow to the other cabinet, thereby reducing a likelihood of overheating and/or providing redundancy while remedial actions occur.

FIG. 3B illustrates a schematic perspective view of an embodiment of an environment 310 in which a portion of the cooling cabinets 302 have been removed to permit access to an interior portion 312 associated with the cooling-air plenum 306. As shown, the respective cooling cabinets 302 include a fan 314 that may be used to drive air flow through the cooling cabinet and into an associated electronics enclosure (not pictured) via the cooling-air plenum 306. For example, one or more openings may be formed to permit passage of air via the cooling-air plenum 306.

In this example, one or more flow control devices 316 are associated with the cooling cabinets 302 and/or the coupling passages 304. For example, the one or more flow control devices 316 in this example may be formed along a wall portion 318 of the cooling cabinets 302. In embodiments, the one or more flow control devices 316 permit selective, independent passage of air flow between adjacent cabinets via the coupling passages 304. The non-limiting example flow control devices 316 in FIG. 3B include louvers 320 with slats 322 that are movable to adjust a cross-sectional flow area along the coupling passages 304. Movement of the slats 322 may correspond to a fully closed position, blocking flow, a fully open position, permitting flow at a maximum cross-sectional flow area, and/or any position between. As discussed herein, one or more control systems may be used to adjust a position of the one or more flow control devices 316 to permit or restrict flow based, at least in part, on one or more metrics associated with one or more operational parameters that may be determined and/or inferred using information from one or more sensors.

As discussed herein, the configuration shown in FIG. 3B includes the coupling passages 304 having a length 324 such that the individual cooling cabinets 302 are separated and/or not in contact with one another. It should be appreciated that the length 324 may be varied and/or adjusted based, at least in part, on factors such as installation space within the datacenter, among others. Furthermore, various components such as seals, gaskets, and/or the like may be included to maintain enclosed and/or regulated airflow within the cooling cabinets 302.

FIG. 3C illustrates a schematic perspective view of an embodiment of an environment 330 in which a portion of the cooling cabinets 302 have been removed to permit access to the interior portion 312 associated with the cooling-air plenum 306, the heated-air plenum 308, and a flow path 332 between the heated-air plenum 308 and the cooling-air plenum 306 that includes a cooling coil 334. In at least one embodiment, the illustrated fan 314 includes a centrifugal fan. Further illustrated is a hemisphere associated with an area of avoidance on the suction side. In operation, air flow is directed from the heated-air plenum 308, along the flow path 332, through the cooling coil 334, and to the cooling-air plenum 306. Along the flow path 332, heat may be removed from the air at the cooling coil 334, thereby providing cooled air for the associated cabinet enclosure (not pictured) and/or for direction into an adjacent cabinet enclosure 302.

As shown in this example, the flow control device 316 is in an open position such that cooled air may flow into the adjacent cooling cabinet 302 (e.g., from the cooling cabinet 302N to the cooling cabinet 302D via the cooling passage 304N). It should be appreciated that other follow control devices 316 may be independently operable so that flow would be blocked or otherwise maintained within the cooling cabinet 302D. Furthermore, while the illustrated configuration in FIG. 3C includes the flow control device 316 coupling the cooling cabinet 302N to the cooling cabinet 302D at the cooling-air plenum 306, various embodiments may alternatively, or additionally, including one or more additional flow control devices 316 and/or one or more additional coupling passages 304, between the respective heated-air plenums 308, along the flow paths 332, and/or combinations thereof.

As shown in FIG. 3C, the pair of cooling cabinets 302D, 302N are coupled together via the coupling passage 304, which in this example are associated with the one or more flow control devices 316 that may selectively permit flow along the coupling passage 304. For example, one or more portions of the flow control devices 316 may be actuated or otherwise controlled to move between opened and closed positions, such as the illustrated louvers 320. For example, the slats 322 may rotate about one or more axes responsive to a control signal, such as a signal indicative of a fan failure or the like to permit sharing of air between adjacent cooling cabinets 302. In the illustrated example, the louvers 320 are in an open position, thereby permitting transfer or air between the cabinets. The transferred air may be cooled air that can then be distributed to an electronics enclosure and/or redirected to other cooling cabinets 302. Accordingly, systems and methods of the present disclosure may use the coupling passages 304 to bleed cold air into an adjacent cabinet should that cabinet experience a mechanical or electrical component failure to provide redundancy. Moreover, if a cabinet starts to over-heat (e.g., from excessive kW load), the cabinet can receive the same bleed air to support greater cooling.

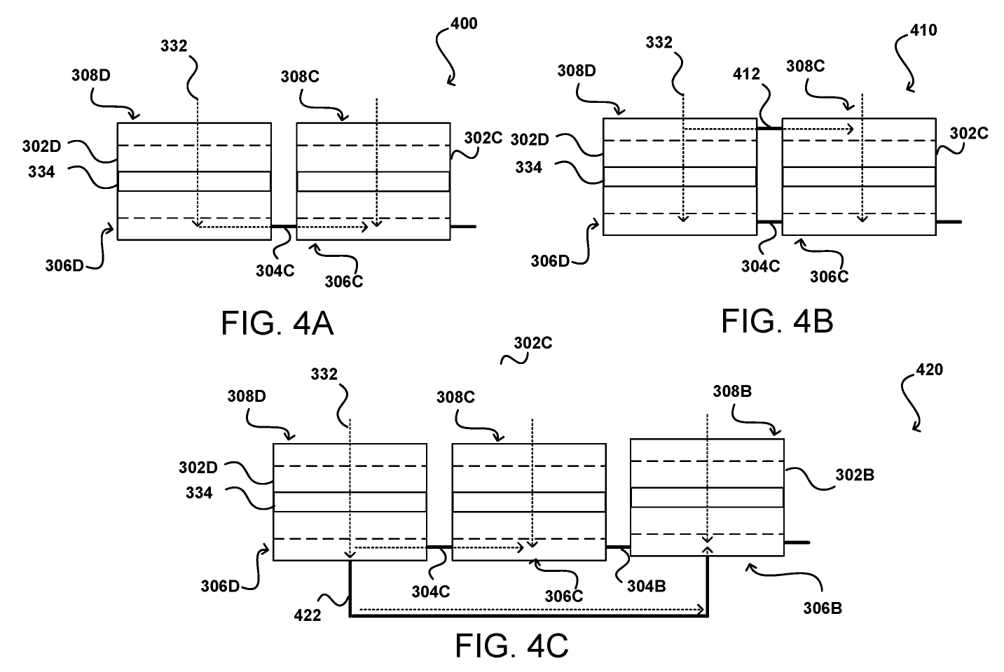

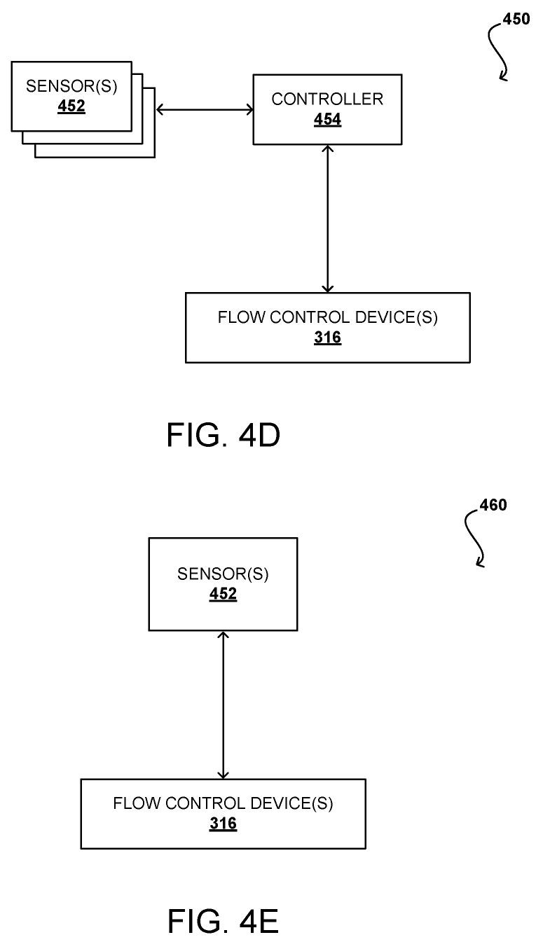

FIGS. 4A-4C illustrate schematic top view representations of different redundant cooling configurations that may be used with embodiments of the present disclosure. FIG. 4A illustrates an example configuration 400 with a pair of cooling cabinets 302C, 302D arranged adjacent to one another and coupled together via the coupling passage 304C. In operation, air (e.g., heated air that is heated by removing heat generated by one or more heat generating component within an electronics cabinet) may enter the cooling cabinets 302C, 302D via the heated-air plenum 308D, be driven along the flow path 332 by one or more fans, be cooled by the cooling coil 334, and then enter the cooling-air plenum 306. In the example configuration, at least a portion of the air may be redirected into the cooling cabinet 302C via the coupling passage 304C, which may connect the respective cooling-air plenums 306C, 306D together. In this manner, cooling air may be provided to the cooling cabinet 302C, for example, if it is determined that temperatures exceed one or more targets, that equipment has failed or is operating inefficiently, and/or the like.

FIG. 4B illustrates an example configuration 410 in which a second coupling passage 412 is provided between the cooling cabinet 302C and the cooling cabinet 302D to fluidly couple the respective heated-air plenums 308C, 308D together. That is, heated air may be redirected to a different cooling cabinet 302, for example, based on different metrics or sensors readings. By way of example, if an electronics cabinet is experiencing higher load than other, it may be desirable to redirect some of the heated air together a cabinet with less load that may be able to more efficiently cool the air, the cooled aid may then be provided back to the original cabinet, for example via the coupling passage 304C, or another cabinet may be used to provide cooled air. In this manner, systems and methods may provide multiple alternative configurations to balancing and redirecting air within the cabinets to account for a variety of different operational configurations.

FIG. 4C illustrates an example configuration 420 in which non-adjacent cooling cabinets 302B, 302D are coupled together via a coupling passage 422. It should be appreciated that while the coupling passage 422 is shown to extend directly between the cooling cabinet 302D and the cooling cabinet 302B, in one or more embodiments, the coupling passage 422 may extend from and/or couple to the other coupling passages 304C, 304B. In operation, one or more flow control devices may be associated with coupling passage 422, as discussed herein with respect to the flow control devices 316, and may be operable responsive to one or more determinations and/or sensor readings to redirect air between cooling cabinets.

As discussed herein, one or more embodiments of the present disclosure may use sensor information, which may include information acquired from one or more sensors, information derived or inferred from one or more sensors, and/or the like, to control, at least in part, operation of the one or more flow control devices 316. FIGS. 4D and 4E illustrate schematic control configurations 450, 460 that may be used with one or more embodiments of the present disclosure. For example, the one or more sensors 452 may be capable of determining, or being used to determine, air flow rates, air temperatures, cooling fluid flow rates, fan speed, electrical load, pressure readings, and/or the like. Furthermore, one or more metrics may be assigned and/or inferred based on different sensor information, such as assigning a particular cooling cabinet a level (e.g., green, yellow, red) or likelihood of failure (e.g., low, medium, high), and/or the like. For example, metrics may be derived from sensor readings, such as evaluations against one or more thresholds, comparisons to different ranges, evaluations of trends over time, and/or combinations thereof. As discussed herein, different sensor information may be used, such as airflow sensors, temperature sensors, pressure sensors, fluid flow sensors, load sensors, and/or the like. In at least one embodiment, a control system may be used to receive sensor readings to determine one or more metrics, such as a value that is indicative of a state or condition of a cooling cabinet, and compare the value to one or more thresholds to determine an action for the flow control device(s) 316, which may include no action, causing the flow control device(s) 316 to open or close some percentage to regulate flow between cooling cabinets, and/or the like.

Furthermore, the one or more sensors 452 may also be associated with obtaining information about the flow control devices 316, such a current variable flow control element position, a flow control device status, a flow control device health, and/or the like. For example, it may be determined, based on one or more sensor readings, that an actuator or other component for a flow control device is malfunctioning or non-operational. Such a determination may lead to an alarm or indicator to one or more operators to schedule maintenance operations. Additionally, sensor information associated with the flow control device(s) 316 may also be used to adjust or select one or more alternative flow control schemes, such as using a bypass to redirect flow between non-adjacent cooling cabinets.

In this example, the one or more sensors 452 provide information to a controller 454 (e.g., a control system). The sensors 452 may be arranged around different areas of the cabinet, for example in hot/cold aisles, in storage/cooling sections, and/or the like. Furthermore, the sensors 452 may be associated with different components or equipment, such as the fans, cooling fluid loops, and/or the like. The controller 454 may use the information from the one or more sensors 452 to determine a state or condition for a cooling cabinet, which may be associated with a determination of fan speed, cooling air temperature, cooling fluid temperature, cooling fluid flow rate, and/or the like. The state or condition may be used as a target or setpoint for controlling the one or more flow control device(s) 316 to determine, for example, whether to provide additional cooling air or modify other flow parameters for different cooling cabinets. For example, if a state is associated with a failure or other error, a signal may be transmitted to the one or more flow control device(s) 316 to permit flow through associated connecting passages. In this manner, sensor information may be used to control flow control device positions.

FIG. 4B illustrates the example control configuration 460 that uses a direct measurement between the one or more sensors 452 to control, at least in part, the one or more flow control devices 316. For example, the one or more sensors 452 may be associated with a fan operational condition, and if the one or more sensors 452 indicate a fan failure, the one or more flow control devices 316 may be alerted to open to facilitate sharing of cooling air to reduce a likelihood of a cooling cabinet, and associated electronics cabinet, overheating.

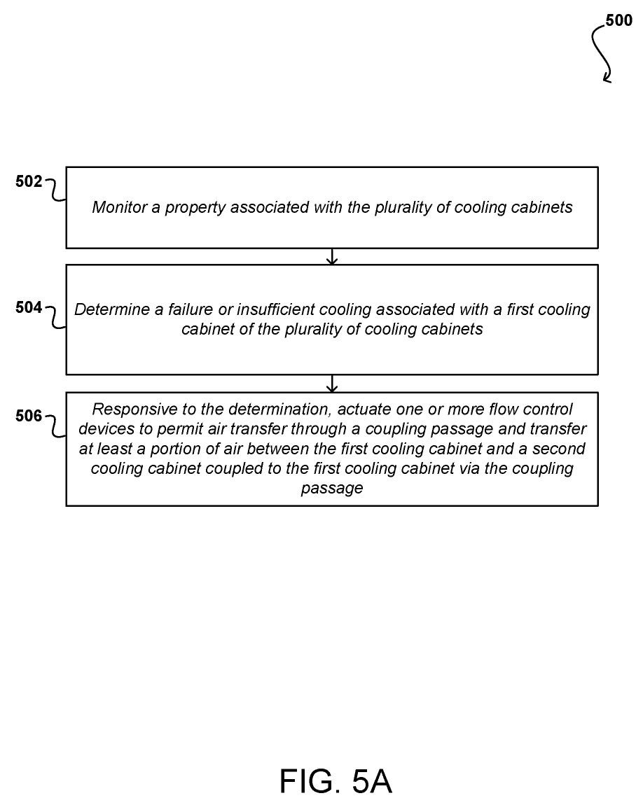

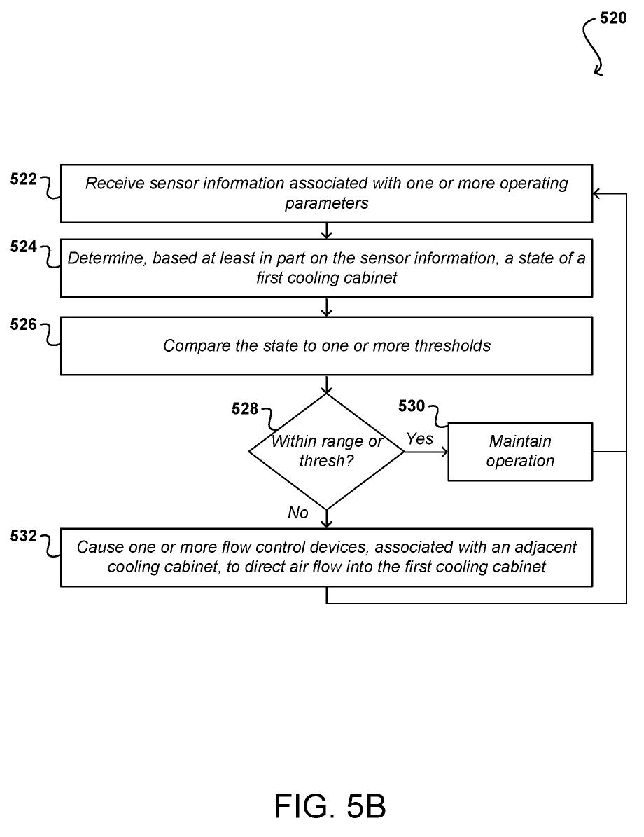

FIG. 5A illustrates an example flow chart for a process 500 for transferring air between connected cooling cabinets. It should be appreciated that steps for the method may be performed in any order, or in parallel, unless otherwise specifically stated. Moreover, the method may include more or fewer steps. In this example, property associated with the plurality of cooling cabinets is monitored 502. In at least one embodiment, the plurality of cooling cabinets may each be attached to a corresponding electronics enclosure. Furthermore, various embodiments may include a coupling passage between a first cooling cabinet and an adjacent second cooling cabinet. A flow control device may be associated with the coupling passage. In one or more embodiments, a failure or insufficient cooling associated with the first cooling cabinet is determined 504. For example, different sensor information may be used to determine the failure or insufficient cooling, which may correspond to one or more states. Thereafter, responsive to the determining, one or more embodiments may actuate the flow control device to permit air transfer through the coupling passage and transfer at least a portion of air between the first and second cooling cabinets 506. In this manner, cooling air flow may be shared or redirected between coupled cooling cabinets.

FIG. 5B illustrates an example flow chart for a process 520 for transferring air between connected cooling cabinets. In this example, sensor information is received 522. The sensor information may be associated with one or more enclosure operating conditions, such as pressure, temperature, cooling air flow rate, cooling fluid flow rate, load, fan operating conditions, and/or combinations thereof. One or more embodiments may determine a state for a first cooling cabinet 524. For example, state may be associated with whether or not operating parameters are within a range, whether or not certain equipment is operating, and/or the like. The determined state may be compared to one or more thresholds 526, which may be used to determine whether or not operating is within a target range or threshold 528. The target range may evaluate whether a likelihood of error is greater than a threshold, whether operational parameters are trending in a positive or negative direction, and/or the like. If so, operation may continue 530. If not, then one or more flow control devices, associated with an adjacent cooling cabinet, may be operated to cause air flow, from the adjacent cooling cabinet, into the first cooling cabinet 532. Accordingly, cooling cabinet states may be used to regulate shared or redirected air flow.

It should be appreciated that while one or more embodiments of the present disclosure may refer to comparisons with one or more thresholds, that embodiments may be used to compare one or more operating parameters or state to at least one of (i) one or more target values, (ii) one or more allowable ranges, (iii) one or more thresholds, or (iv) one or more target operating parameters. Furthermore, control logic may be used to derive one or more indicators that may be associated, at least in part, cooling cabinet states, such as a filtered or estimated values, multi-point aggregations, and/or the like. Accordingly, indicators or other inferences may be used to provide a representative indicator, which may be numerical or non-numerical, to represent cooling cabinet states. In this manner, embodiments of the present disclosure may be used to adjust features of the flow control devices based on one or more control criteria, which may include a variety of cabinet metrics.

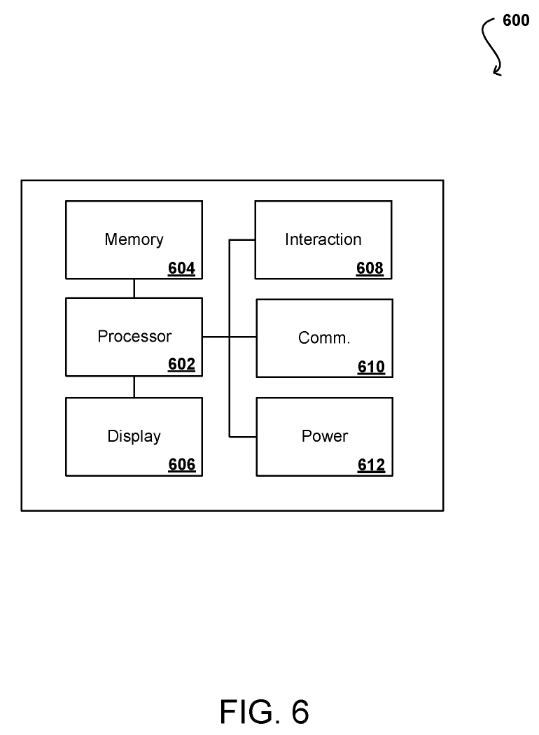

FIG. 6 illustrates a set of general components of an example computing device 600. In this example, the device includes a processor 602 for executing instructions that can be stored in a memory 604. The device can include many types of memory, data storage, or non-transitory computer-readable storage media, such as a first data storage for program instructions for execution by the processor 602, a separate storage for images or data, a removable memory for sharing information with other devices, etc. The device may optionally include a display element 606, such as a touch screen or liquid crystal display (LCD), although devices such as portable media players might convey information via other means, such as through audio speakers, and other devices may not include displays, such as server components executing within data centers, among other options. As discussed, the device in many embodiments will include at least one interaction component 608 able to receive input from a user. This input can include, for example, a push button, touch pad, touch screen, wheel, joystick, keyboard, mouse, keypad, or any other such device or element whereby a user can input a command to the device. In some embodiments, however, such a device might not include any buttons at all, and might be controlled only through a combination of visual and audio commands, such that a user can control the device without having to be in contact with the device. In some embodiments, the computing device 600 of FIG. 6 can include one or more network interface or communication components 610 for communicating over various networks, such as a Wi-Fi, Bluetooth, RF, wired, or wireless communication systems. The device may be configured to communicate with a network, such as the Internet, and may be able to communicate with other such devices. The device will also include one or more power components 612, such as power cords, power ports, batteries, wirelessly powered or rechargeable receivers, and the like.

Storage media and other non-transitory computer readable media for containing code, or portions of code, can include any appropriate media known or used in the art, including storage media and communication media, such as but not limited to volatile and non-volatile, removable and non-removable media implemented in any method or technology for storage of information such as computer readable instructions, data structures, program modules, or other data, including RAM, ROM, EEPROM, flash memory or other memory technology, CD-ROM, digital versatile disk (DVD) or other optical storage, magnetic cassettes, magnetic tape, magnetic disk storage or other magnetic storage devices, or any other medium which can be used to store the desired information and which can be accessed by the a system device. Based on the disclosure and teachings provided herein, a person of ordinary skill in the art will appreciate other ways and/or methods to implement the various embodiments.

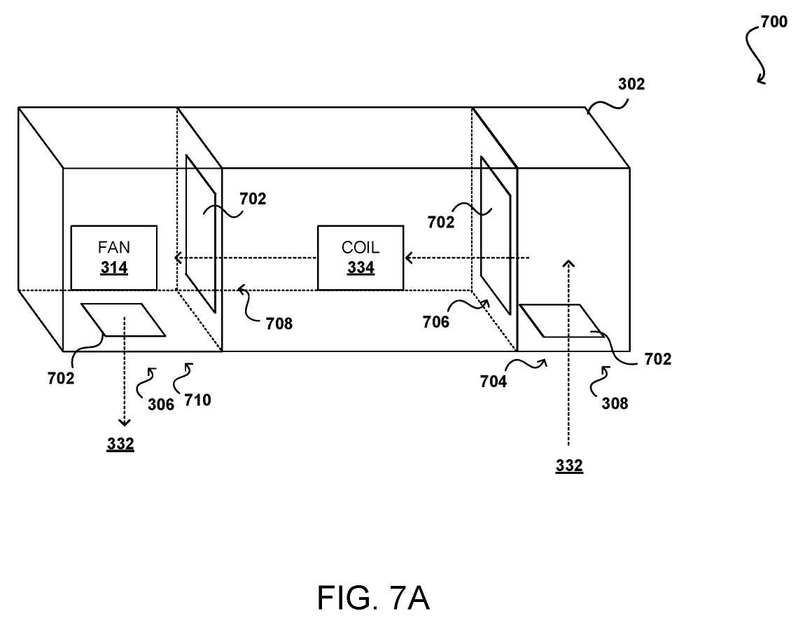

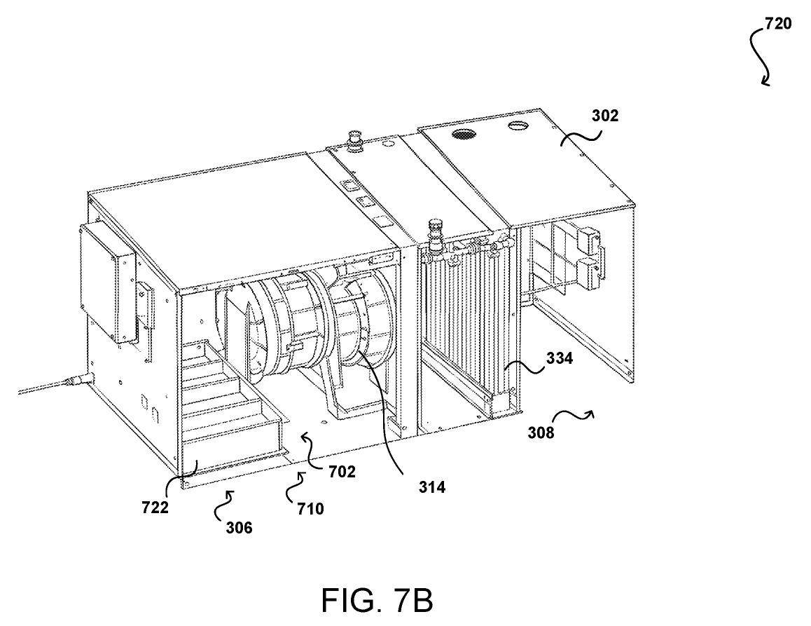

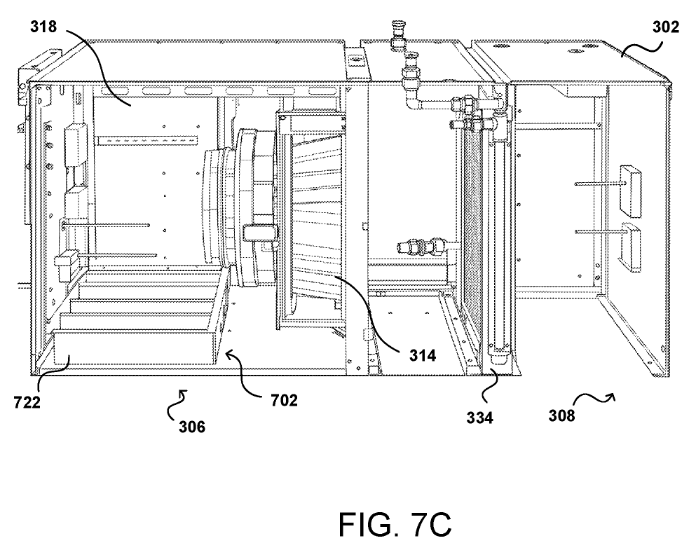

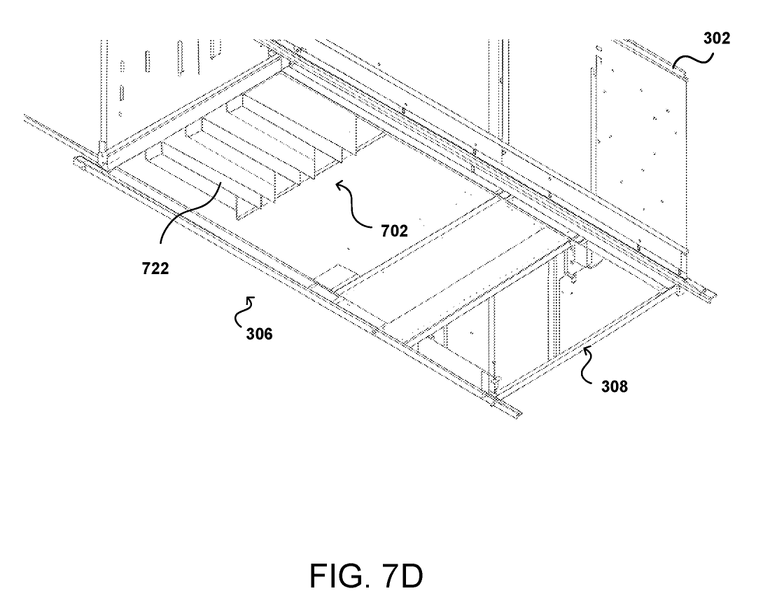

FIG. 7A illustrates an example environment 700 in which one or more variable flow control elements 702 (e.g., dampers) may be integrated into the cooling cabinet 302, which may include integration with or without the associated flow control devices 316. As shown, the one or more variable flow control elements 702 may be arranged at a variety of locations associated with the cooling cabinet 302, including a first inlet 704 to the heated-air plenum 308, a first outlet 706 along the flow path 332, a second inlet 708 toward the cooling-air plenum 306, and second outlet 710 away from the cooling-air plenum 306. When combined with the flow control device 316, one or more embodiments may be used to block or otherwise restrict air flow into and/or out of the cooling cabinet 302. For example, in the event of fan failure, the one or more variable flow control elements 702 may be used to restrict or otherwise block the flow of heated air toward the cooling cabinet and/or may be used to vent or otherwise regulate flow, such as by opening the second outlet 710 to accommodate flow from an adjacent cooling cabinet.

In this example configuration, the cooling cabinet 302 includes the fan 314, but it should be appreciated that multiple fans may be included in embodiments, such as a pair of fans arranged in a push/pull configuration, as discussed herein. In this example, the cooling coil 334 904 is arranged upstream of the fan 314 such that air received at the suction side is cooled air. The cooled air may be cooled by cooling fluid passing through the cooling coil 334. In at least one embodiment, cooling fluid is directed through the coil 334 and air is driven along the coil 334 to cool the air prior to being directed toward an electronics enclosure. In this example, the illustrated fan may be substantially centered or otherwise positioned within an enclosed area, but in other embodiments the fan 314 may be arranged in different positions in order to facilitate air flow, inclusion of additional fans, and/or the like.

FIG. 7B illustrates an example environment 720 of the cooling cabinet 302 including a perspective view of the one or more one or more variable flow control elements 702 (e.g., dampers) in which one or more features or panels are removed. In this example, the configuration is simplified such that the variable flow control element 702 is associated with the cooling-air plenum 306. The non-limiting example variable flow control element 702 includes a damper with one or more moveable plates 722 (e.g., blades, louvers, etc.) within the ductwork associated with cooling-air plenum 306. The variable flow control element 702 may be used to regulate air flow and redirect the air flow to a particular area or region, thereby providing zoning or zone control for different flow rates.

This example includes blades as the plates 722 that may pivot about an axis in order to regulate flow through the enclosure. It should be appreciated that other types of dampers may be used within the scope of the present disclosure, including, by way of non-limiting examples, butterfly dampers, louver dampers, and/or combinations thereof.

In operation, the variable flow control element 702 may be used to prevent or reduce a likelihood of undesirable reversal of air flow in the event of a motor or fan failure. For example, if the fan 314 had a motor failure, pressure differentials may drive air back up into the cooling cabinet 302. Embodiments of the present disclosure may use one or more control systems to close the plates 722 (e.g., fully close, partially close, etc.) responsive to one or more indicators associated with a failure. For example, one or more sensors may be positioned to obtain data for operation of the fan and/or motor and transmit the data to one or more control systems. Upon determining operational drops below a threshold or target (e.g., a state), the one or more control systems may cause the variable flow control element 702 to operate with a specific configuration (e.g., a percentage open) based on one or more target operating conditions. In this manner, flow may be controlled within the cabinet enclosure and cooling cabinet 302. It should be appreciated that the position of the variable flow control element 702 is by way of example and is not intended to limit or otherwise restrict the scope of the present disclosure, as discussed herein.

FIG. 7C illustrates a perspective side view in which a portion of the cooling cabinet 302 is removed. The illustrated fan 314 is shown removed from the cooling coil 334, for example by a set distance that may be based, at least in part, on one or more target cooling capabilities. The variable flow control element 702 is further shown with a skirt, and therefore, is not flush with a bottom of the cooling cabinet 302. The skirt is shown by way of example and other embodiments may include a smaller skirt, a bigger skirt, or may integrate the variable flow control element 702 and/or the plates 722 into the body of the cooling cabinet 302. While not shown in this embodiment, various configurations may also integrate the one or more flow control devices 316, for example, into the wall 318.

FIG. 7D illustrates a bottom perspective view of the cooling cabinet 302 illustrating the plates 722 in open position. As shown, the plates 722, when positioned on a cabinet enclosure, would extend into the cabinet enclosure and/or into a plenum between the cabinet enclosure and the cooling cabinet 302. In operation, the plates 722 may rotate about respective axes in order to decrease a cross-sectional flow area associated with the variable flow control element 702. As discussed, the plates 722 may rotate collectively as a unit or may be individually controllable. Additionally, embodiments may include separate control of groups of plates 722.

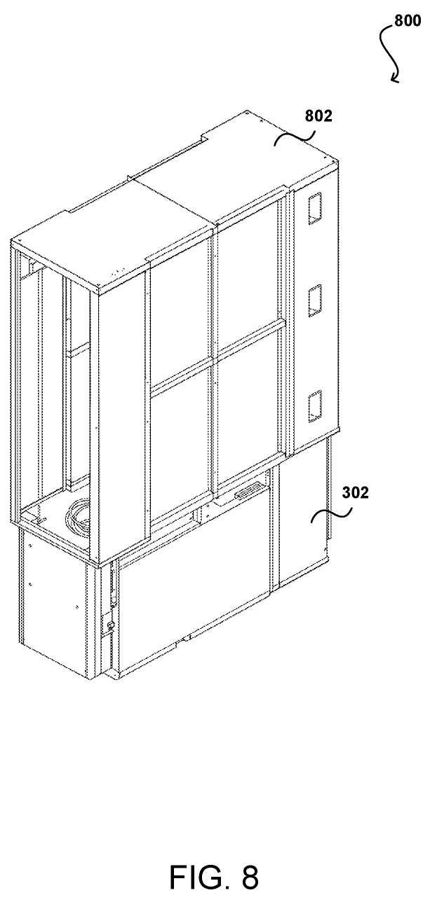

FIG. 8 illustrates a perspective view of an embodiment of a cooling configuration 800 in which the cooling cabinet 302 is arranged axially lower than (e.g., beneath) a cabinet enclosure 802. The cooling cabinet 302 may include one or more features of the cooling cabinets discussed herein, for example a cooling coil, fans, dampers, louvers, and/or the like. In at least one embodiment, arranging the cooling cabinet 302 lower than the cabinet enclosure 802 may reduce a likelihood of fluid ingress into the cabinet enclosure 802 in the event of a leak in the cooling cabinet 302. For example, a leak in the cooling cabinet 302 would likely pool along a bottom. In embodiments where the enclosure 802 is below the cooling cabinet 302, fluid could potentially leak through and into the enclosure 802. While elevating the enclosure 802 may reduce accessibility to certain parts of the enclosure 802, various embodiments may incorporate a riser or walkway to provide access to the enclosure 802. Additionally, or alternatively, existing datacenters with raised floor cooling may accommodate the illustrated configuration by positioning the cooling cabinet 302 on the subfloor.

In one or more embodiments, different cross-sectional areas, flow areas, flow volumes, and the like may be particularly selected based on one or more factors or preferences for cooling capacity. For example, a larger interior volume may be provided to facilitate greater movement of air. As another example, one or more dimensions may be modified to direct or otherwise target air flow to particular areas. In this manner, systems and methods of the present disclosure may be configured for one or more specific cooling requirements.

Various embodiments discussed herein may include one or more dimensions particularly selected for operation with a given cabinet enclosure and/or a target operating configuration. For example, cabinets may be between approximately 24 inches and 30 inches wide. Wider cabinets may be used to accommodate internal cable management, among other benefits. Similarly, motor/fan configurations may be selected based, at least in part, on target capacity (e.g., CFM). Moreover, embodiments may include seals and/or the like to achieve NEMA 3R compliance and UL listing.

Embodiments may also be described in view of the following clauses:
1. A cooling system, comprising:
   a plurality of electronics enclosures; and
   a plurality of cooling cabinets each attached to a corresponding electronics enclosure of the plurality of electronics enclosures,
   wherein a coupling passage is arranged between a first cooling cabinet and an adjacent second cooling cabinet to selectively permit air transfer between the first and second cooling cabinets.
2. The cooling system of clause 1, wherein each cooling cabinet comprises:
   a heated-air plenum;
   a cooling coil through which air supplied from the heated-air plenum passes;
   a cooling-air plenum into which air having passed through the cooling coil flows; and a fan configured to drive the air.
3. The cooling system of clause 2, wherein the coupling passage is configured to couple a cooling-air plenum of the first cooling cabinet with a cooling-air plenum of the second cooling cabinet, and
   wherein the coupling passage includes a first flow control device configured to block or permit air transfer through the coupling passage.
4. The cooling system of clause 3, further comprising:
   a return passage coupling a heated-air plenum of the first cooling cabinet with a heated-air plenum of the second cooling cabinet; and
   a second flow control device arranged on the return passage and configured to block or permit air transfer through the return passage.
5. The cooling system of clause 4, further comprising a controller configured to:
   monitor a property associated with the plurality of cooling cabinets; and
   responsive to a determination of a failure or insufficient cooling associated with the first cooling cabinet:
   actuate the first flow control device to permit air transfer through the coupling passage, and
   actuate the second flow control device to permit air transfer through the return passage, to transfer at least a portion of air between the first and second cooling cabinets.
6. The cooling system of clause 5, wherein the property includes at least one of a fan speed and a cooling water flow.
7. The cooling system of clause 5, wherein, responsive to the determination, the controller is configured to increase at least one of (i) a fan speed and (ii) an airflow rate of the fan in the second cooling cabinet.
8. A cooling cabinet configured to be attached to an electronics enclosure, the cooling cabinet comprising:
   a cabinet housing, wherein the cooling cabinet is configured for connection to a coupling passage arranged between the cooling cabinet and an adjacent cooling cabinet to selectively permit air transfer between the cooling cabinet and the adjacent cooling cabinet, the coupling passage including a flow control device configured to block or permit the air transfer.
9. The cooling cabinet of clause 8, wherein, in an internal air path of the cooling cabinet, a heated-air plenum, a cooling coil, a fan, and a cooling-air plenum are arranged in an ordered configuration from an upstream side toward a downstream side,
   wherein the fan is a centrifugal fan having an axis along a flow direction, and wherein an outlet of the cooling cabinet is located downstream of an outlet of the centrifugal fan in the flow direction.
10. The cooling cabinet of clause 8, further comprising:
   a second flow control device at an outlet of the cooling cabinet, the second flow control device configured to regulate at least one of i) flow into the electronics enclosure or ii) flow out of the electronics enclosure.
11. The cooling cabinet of clause 8, wherein a position of the flow control device associated with the blocking or permitting of the air transfer is based, at least in part, on at least one of i) a fan speed and (ii) an airflow rate of the fan.
12. The cooling cabinet of clause 8, wherein the cooling cabinet is further coupled to a non-adjacent cooling cabinet via a second coupling passage including a second flow control device configured to block or permit the air transfer through the second coupling passage.
13. The cooling cabinet of clause 12, wherein the second coupling passage is fluidly connected to the coupling passage.
14. The cooling cabinet of clause 8, wherein the cooling cabinet is arranged axially below the electronics enclosure.
15. The cooling cabinet of clause 8, wherein the coupling passage is associated with at least one of a heated-air plenum or a cooling-air plenum.
16. The cooling cabinet of clause 15, wherein the coupling passage includes a first coupling passage associated with the heated-air plenum and a second coupling passage associated with the cooling-air plenum.
17. A method of operating a cooling system including a plurality of cooling cabinets each attached to a corresponding electronics enclosure, the cooling system including a coupling passage between a first cooling cabinet and an adjacent second cooling cabinet, the coupling passage including a flow control device, the method comprising:
   monitoring a property associated with the plurality of cooling cabinets;
   determining a failure or insufficient cooling associated with the first cooling cabinet; and responsive to the determining, actuating the flow control device to permit air transfer through the coupling passage and transfer at least a portion of air between the first and second cooling cabinets.
18. The method of clause 17, wherein the property includes at least one of a fan speed and a cooling water flow.
19. The method of clause 17, further comprising: responsive to the determining, actuating a second flow control device to permit air transfer through a second coupling passage and transfer at least a portion of air between the first cooling cabinet and a non-adjacent third cooling cabinet.
20. The method of clause 19, wherein the second coupling passage is coupled to the coupling passage.

Although the technology herein has been described with reference to particular embodiments, it is to be understood that these embodiments are merely illustrative of the principles and applications of the present technology. It is therefore to be understood that numerous modifications may be made to the illustrative embodiments and that other arrangements may be devised without departing from the spirit and scope of the present technology as defined by the appended claims.

What is claimed is:

1. A cooling system, comprising:
a plurality of electronics enclosures; and
a plurality of cooling cabinets each attached to a corresponding electronics enclosure of the plurality of electronics enclosures,
wherein a coupling passage is arranged between a first cooling cabinet and an adjacent second cooling cabinet to selectively permit air transfer between the first and second cooling cabinets.

2. The cooling system of claim 1, wherein each cooling cabinet comprises:
a heated-air plenum;
a cooling coil through which air supplied from the heated-air plenum passes;
a cooling-air plenum into which air having passed through the cooling coil flows; and
a fan configured to drive the air.

3. The cooling system of claim 2, wherein the coupling passage is configured to couple a cooling-air plenum of the first cooling cabinet with a cooling-air plenum of the second cooling cabinet, and
wherein the coupling passage includes a first flow control device configured to block or permit air transfer through the coupling passage.

4. The cooling system of claim 3, further comprising:
a return passage coupling a heated-air plenum of the first cooling cabinet with a heated-air plenum of the second cooling cabinet; and
a second flow control device arranged on the return passage and configured to block or permit air transfer through the return passage.

5. The cooling system of claim 4, further comprising a controller configured to:
monitor a property associated with the plurality of cooling cabinets; and
responsive to a determination of a failure or insufficient cooling associated with the first cooling cabinet:
actuate the first flow control device to permit air transfer through the coupling passage, and
actuate the second flow control device to permit air transfer through the return passage, to transfer at least a portion of air between the first and second cooling cabinets.

6. The cooling system of claim 5, wherein the property includes at least one of a fan speed and a cooling water flow.

7. The cooling system of claim 5, wherein, responsive to the determination, the controller is configured to increase at least one of (i) a fan speed and (ii) an airflow rate of the fan in the second cooling cabinet.

8. A cooling cabinet configured to be attached to an electronics enclosure, the cooling cabinet comprising:
a cabinet housing, wherein the cooling cabinet is configured for connection to a coupling passage arranged between the cooling cabinet and an adjacent cooling cabinet to selectively permit air transfer between the cooling cabinet and the adjacent cooling cabinet, the coupling passage including a flow control device configured to block or permit the air transfer.

9. The cooling cabinet of claim 8, wherein, in an internal air path of the cooling cabinet, a heated-air plenum, a cooling coil, a fan, and a cooling-air plenum are arranged in an ordered configuration from an upstream side toward a downstream side,
wherein the fan is a centrifugal fan having an axis along a flow direction, and wherein an outlet of the cooling cabinet is located downstream of an outlet of the centrifugal fan in the flow direction.

10. The cooling cabinet of claim 8, further comprising:
a second flow control device at an outlet of the cooling cabinet, the second flow control device configured to regulate at least one of i) flow into the electronics enclosure or ii) flow out of the electronics enclosure.

11. The cooling cabinet of claim 8, wherein a position of the flow control device associated with the blocking or permitting of the air transfer is based, at least in part, on at least one of i) a fan speed and (ii) an airflow rate of the fan.

12. The cooling cabinet of claim 8, wherein the cooling cabinet is further coupled to a non-adjacent cooling cabinet via a second coupling passage including a second flow control device configured to block or permit the air transfer through the second coupling passage.

13. The cooling cabinet of claim 12, wherein the second coupling passage is fluidly connected to the coupling passage.

14. The cooling cabinet of claim 8, wherein the cooling cabinet is arranged axially below the electronics enclosure.

15. The cooling cabinet of claim 8, wherein the coupling passage is associated with at least one of a heated-air plenum or a cooling-air plenum.

16. The cooling cabinet of claim 15, wherein the coupling passage includes a first coupling passage associated with the heated-air plenum and a second coupling passage associated with the cooling-air plenum.

17. A method of operating a cooling system including a plurality of cooling cabinets each attached to a corresponding electronics enclosure, the cooling system including a coupling passage between a first cooling cabinet and an adjacent second cooling cabinet, the coupling passage including a flow control device, the method comprising:
monitoring a property associated with the plurality of cooling cabinets;
determining a failure or insufficient cooling associated with the first cooling cabinet; and
responsive to the determining, actuating the flow control device to permit air transfer through the coupling passage and transfer at least a portion of air between the first and second cooling cabinets.

18. The method of claim 17, wherein the property includes at least one of a fan speed and a cooling water flow.

19. The method of claim 17, further comprising:
responsive to the determining, actuating a second flow control device to permit air transfer through a second coupling passage and transfer at least a portion of air between the first cooling cabinet and a non-adjacent third cooling cabinet.

20. The method of claim 19, wherein the second coupling passage is coupled to the coupling passage.
